(19) United States
(12) Patent Application Publication
(10) Pub. No.: US 2025/0386652 A1
(43) Pub. Date: Dec. 18, 2025

(54) LIGHT-EMITTING DEVICE

(71) Applicant: NICHIA CORPORATION, Anan-shi (JP)

(72) Inventor: Daisuke NIKI, Tokushima-shi (JP)

(73) Assignee: NICHIA CORPORATION, Anan-shi (JP)

(21) Appl. No.: 19/226,671

(22) Filed: Jun. 3, 2025

(30) Foreign Application Priority Data
Jun. 17, 2024 (JP) 2024-097563

(51) Int. Cl. H10H 29/856; H10H 29/01; H10H 29/85

(52) U.S. Cl. CPC H10H 29/856; H10H 29/0363; H10H 29/0365; H10H 29/8581

(57) ABSTRACT

A light-emitting device includes: a first light-emitting unit including: a first light-emitting element having a first element lateral surface, and a first light-transmissive member disposed over the first light-emitting element and having a first lateral surface; a second light-emitting unit including: a second light-emitting element having a second element lateral surface facing the first element lateral surface, and a second light-transmissive member disposed over the second light-emitting element and having a second lateral surface facing the first lateral surface; and a reflective member holding the first light-emitting unit and the second light-emitting unit together, wherein the reflective member includes: a first reflective member and a second reflective member.

### CROSS-REFERENCE TO RELATED APPLICATION

This application claims priority to Japanese Patent Application No. 2024-097563, filed on Jun. 17, 2024, the disclosure of which is hereby incorporated by reference in its entirety.

### TECHNICAL FIELD

The present disclosure relates to a light-emitting device.

### BACKGROUND

For example, Japanese Patent Publication No. 2020-107728 discloses a light-emitting device in which covering members are provided between a plurality of light-emitting elements arranged on a substrate and between light-transmitting members on the light-emitting elements.

### SUMMARY

An object of the present disclosure is to provide a light-emitting device that can emit light with a high contrast and increase heat dissipation.

According to an aspect of the present disclosure, a light-emitting device includes a first light-emitting unit including a first light-emitting element having a first element lateral surface and a first light-transmissive member disposed over the first light-emitting element and having a first lateral surface, a second light-emitting unit including a second light-emitting element having a second element lateral surface facing the first element lateral surface and a second light-transmissive member disposed over the second light-emitting element and having a second lateral surface facing the first lateral surface, and a reflective member configured to hold the first light-emitting unit and the second light-emitting unit together. The reflective member includes a first reflective member continuously covering the first element lateral surface, the second element lateral surface, the first lateral surface, and the second lateral surface, and containing a first additive, and a second reflective member disposed between the first light-emitting element and the second light-emitting element and containing a second additive having a thermal conductivity higher than a thermal conductivity of the first additive, and a light reflectance of the first additive is higher than a light reflectance of the second additive.

According to an aspect of the present disclosure, a light-emitting device includes a light-emitting unit including a light-emitting element having an element lateral surface and a light-transmissive member disposed over the light-emitting element and having a lateral surface, a first reflective member covering the element lateral surface of the light-emitting element and the lateral surface of the light-transmissive member and containing a first additive, and a second reflective member covering the first reflective member covering the element lateral surface of the light-emitting element and containing a second additive having a thermal conductivity higher than a thermal conductivity of the first additive. A light reflectance of the first additive is higher than a light reflectance of the second additive.

The present disclosure can provide a light-emitting device that can emit light with a high contrast and increase heat dissipation.

### BRIEF DESCRIPTION OF DRAWINGS

FIG. 1 is a schematic plan view of a light-emitting device according to a first embodiment.

FIG. 2 is a schematic cross-sectional view taken along line II-II in FIG. 1.

FIG. 3 is a schematic cross-sectional view of a light-emitting device according to a first variation of the first embodiment.

FIG. 4 is a schematic cross-sectional view of a light-emitting device according to a second variation of the first embodiment.

FIG. 5 is a schematic cross-sectional view of a light-emitting device according to a third variation of the first embodiment.

FIG. 6 is a schematic cross-sectional view of a light-emitting device according to a fourth variation of the first embodiment.

FIG. 7 is a schematic cross-sectional view of a light-emitting device according to a second embodiment.

FIG. 8 is a schematic cross-sectional view for illustrating a step of a method for manufacturing the light-emitting device according to the first embodiment.

FIG. 9 is a schematic cross-sectional view for illustrating a step of the method for manufacturing the light-emitting device according to the first embodiment.

FIG. 10 is a schematic cross-sectional view for illustrating a step of the method for manufacturing the light-emitting device according to the first embodiment.

FIG. 11 is a schematic cross-sectional view for illustrating a step of the method for manufacturing the light-emitting device according to the first embodiment.

FIG. 12 is a schematic cross-sectional view for illustrating a step of the method for manufacturing the light-emitting device according to the first embodiment.

FIG. 13 is a schematic cross-sectional view for illustrating a step of the method for manufacturing the light-emitting device according to the first embodiment.

FIG. 14 is a schematic cross-sectional view for illustrating a step of the method for manufacturing the light-emitting device according to the first embodiment.

FIG. 15 is a schematic cross-sectional view for illustrating a step of the method for manufacturing the light-emitting device according to the first embodiment.

FIG. 16 is a schematic cross-sectional view for illustrating a step of the method for manufacturing the light-emitting device according to the first embodiment.

### DETAILED DESCRIPTIONS

A light-emitting device and a method for manufacturing the light-emitting device according to embodiments of the present disclosure are described below with reference to the drawings. The following embodiments are examples of the light-emitting device and the method for manufacturing the light-emitting device for embodying technical concepts of the present embodiments, and limitation to the embodiments to be described below is not intended. Dimensions, materials, shapes, relative arrangements, or the like of constituent members described in the embodiments are not intended to limit the scope of the present disclosure thereto, unless otherwise specified, and are merely exemplary. The sizes, positional relationship, or the like of members illustrated in each of the drawings may be exaggerated for clarity of description. In the following description, members having the same terms and reference characters represent the same or similar members, and a detailed description of these members is omitted as appropriate. As a cross-sectional view, an end view illustrating only a cut surface may be illustrated.

In the following description, terms indicating specific directions or positions (for example, “upper,” “lower,” “horizontal,” “vertical,” and other terms related to those terms) may be used. However, these terms are used merely to make it easy to understand relative directions or positions in the referenced drawing. As long as the relative direction or position is the same as that described in the referenced drawing using the term such as “upper” or “lower,” in drawings other than the drawings of the present disclosure, actual products, and the like, components need not be arranged in the same manner as that in the referenced drawing. When two members are present, the positional relationship expressed by a relative term such as “on,” “upper,” or “below” in the present specification may include a case in which the two members are in contact with each other and a case in which the two members are not in contact with each other and one of the two members is located above (or below) the other member.

In the following drawings, directions may be indicated by an X-axis, a Y-axis, and a Z-axis. An X direction along the X-axis indicates a predetermined direction along a light-emitting surface of a light-emitting device according to an embodiment. A Y direction along the Y-axis indicates a direction orthogonal to the X direction along the light-emitting surface. AZ direction along the Z-axis indicates a direction orthogonal to the light-emitting surface. That is, the light-emitting surface of the light-emitting device according to an embodiment is parallel to an XY plane, and the Z-axis is orthogonal to the XY plane. A direction in which the arrow of the Z axis is directed is referred to as relatively up or upward, and a direction opposite to the arrow of the Z axis is referred to as relatively down or downward.

### First Embodiment

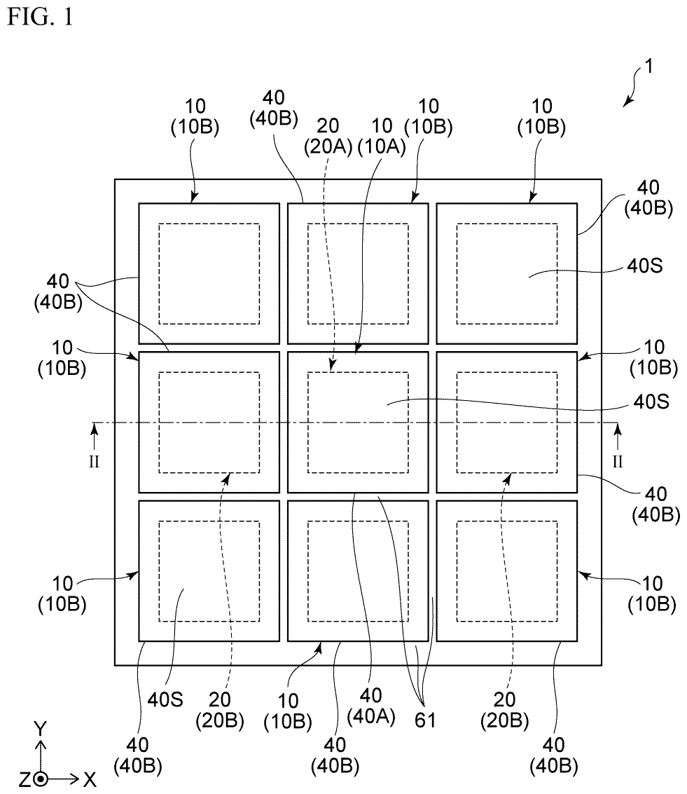

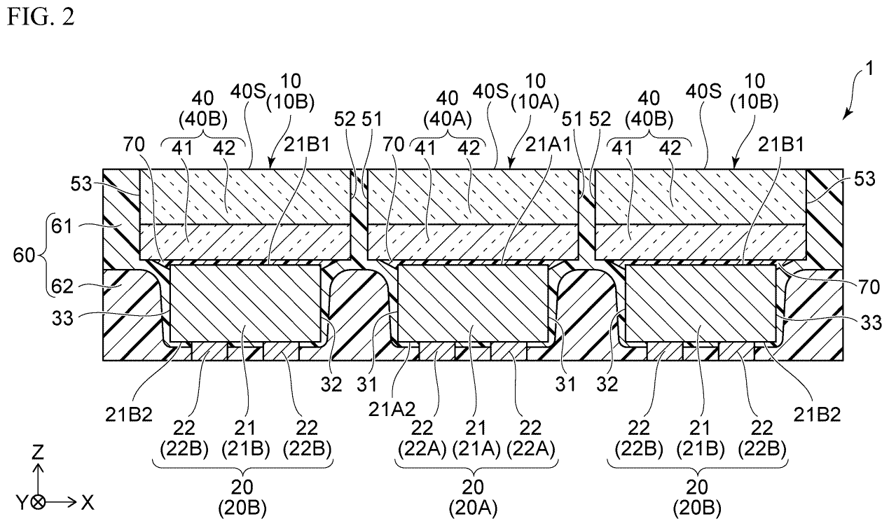

FIG. 1 is a schematic plan view of a light-emitting surface of a light-emitting device 1 according to the first embodiment. FIG. 2 is a schematic cross-sectional view taken along line II-II in FIG. 1.

One direction along the light-emitting surface of the light-emitting device 1, for example, a direction along the X-axis, is referred to as a first direction X. A direction intersecting the first direction X along the light-emitting surface of the light-emitting device 1, for example, a direction along the Y-axis, is referred to as a second direction Y. A direction orthogonal to the light-emitting surface of the light-emitting device 1, for example, a direction along the Z-axis is referred to as a third direction Z. The first direction, the second direction, and the third direction do not have to be along the X-axis, the Y-axis, and the Z-axis, respectively.

The light-emitting device 1 includes a plurality of light-emitting units 10. As illustrated in FIG. 1, the light-emitting device 1 includes, for example, nine light-emitting units 10. For example, 3×3 light-emitting units 10 are arranged in the first direction X and the second direction Y. The number and arrangement of the light-emitting units 10 illustrated in FIG. 1 are merely examples, and the present disclosure is not limited thereto.

In the example illustrated in FIG. 1, the plurality of light-emitting units 10 include an inner light-emitting unit 10A and outer light-emitting units 10B surrounding the inner light-emitting unit 10A in a plan view. For example, a plurality of outer light-emitting units 10B surround one inner light-emitting unit 10A. The number of inner light-emitting units 10A is not limited to one, and may be plural. The outer light-emitting units 10B are located at the outermost peripheral portion of the plurality of light-emitting units 10 in a plan view.

Among the plurality of light-emitting units 10, one of any two light-emitting units 10 adjacent to each other in the first direction X or the second direction Y can be referred to as a first light-emitting unit, and the other can be referred to as a second light-emitting unit. For example, in FIG. 2, among the inner light-emitting unit 10A and the outer light-emitting units 10B adjacent to each other in the first direction X, the inner light-emitting unit 10A can be referred to as the first light-emitting unit and the outer light-emitting unit 10B can be referred to as the second light-emitting unit. In addition, among the inner light-emitting unit 10A and the outer light-emitting units 10B adjacent to each other in the second direction Y, the inner light-emitting unit 10A can be referred to as the first light-emitting unit and the outer light-emitting unit 10B can be referred to as the second light-emitting unit.

The plurality of light-emitting units 10 are not limited to having the inner light-emitting unit 10A and the outer light-emitting units 10B. For example, in the light-emitting device 1 having a total of four light-emitting units 10 in which two light-emitting units 10 are arranged in the first direction X and two light-emitting units 10 are arranged in the second direction Y, it can be said that all of the light-emitting units are located on the outer side (outermost peripheral portion). In this case also, out of the two light-emitting units 10 adjacent to each other in the first direction X or the second direction Y, one can be referred to as the first light-emitting unit and the other can be referred to as the second light-emitting unit.

The light-emitting device 1 can be used as a flash light source for an imaging device, for example. The imaging device is mounted on, for example, a mobile communication terminal. When the light-emitting device 1 including the inner light-emitting unit 10A and the outer light-emitting unit 10B is used as a flash light source of an imaging device, a first light-emitting mode, in which only the inner light-emitting unit 10A is caused to emit light, and a second light-emitting mode, in which the inner light-emitting unit 10A and the plurality of outer light-emitting units 10B are caused to emit light and light having a light distribution angle wider than a light distribution angle in the first light-emitting mode can be emitted, can be switched. For example, when the imaging device is in a telephoto photographing mode, the light-emitting device 1 is switched to the first light-emitting mode, and when the imaging device is in a wide-angle photographing mode, the light-emitting device 1 is switched to the second light-emitting mode.

Details of each component of the light-emitting device 1 are described below.

### Light-emitting Unit

In the following description, the inner light-emitting unit 10A is referred to as the first light-emitting unit, and the outer light-emitting unit 10B adjacent to the inner light-emitting unit 10A is referred to as the second light-emitting unit.

### Light-emitting Element

Each light-emitting unit 10 includes a light-emitting element. A light-emitting element included in the first light-emitting unit (inner light-emitting unit 10A) can be referred to as a first light-emitting element 20A, and a light-emitting element included in the second light-emitting unit (outer light-emitting unit 10B) can be referred to as a second light-emitting element 20B. The first light-emitting element 20A and the second light-emitting element 20B may be simply referred to as a light-emitting element 20 without being distinguished from each other. For example, a plurality of the light-emitting elements 20 in which variations in optical characteristics (luminance, chromaticity, and the like) fall within a predetermined range are selected and used in the light-emitting device 1.

The light-emitting element 20 includes a semiconductor structure. The semiconductor structure of the first light-emitting element 20A can be referred to as a first semiconductor structure 21A, and the semiconductor structure of the second light-emitting element 20B can be referred to as a second semiconductor structure 21B. The first semiconductor structure 21A and the second semiconductor structure 21B may be simply referred to as a semiconductor structure 21 without being distinguished from each other.

The semiconductor structure 21 contains a nitride semiconductor. It is assumed that examples of the nitride semiconductor include semiconductors having all compositions of a chemical formula expressed by InₓAl_{y}Ga_{1-x-y}N (0≤x≤1, 0≤y≤1, x+y≤1) in which the composition ratios of x and y are changed within the respective ranges. Further, it is assumed that examples of the nitride semiconductor also include a semiconductor further containing a group V element other than nitrogen (N) in the above chemical formula, and a semiconductor further containing, in the above chemical formula, various elements added to control various physical properties such as the conductivity type of the semiconductor. The semiconductor structure 21 includes a light-emitting layer. The light-emitting layer can have, for example, a multiple quantum well (MQW) structure including a plurality of barrier layers and a plurality of well layers. Light emitted by the light-emitting layer is ultraviolet light or visible light, for example. The semiconductor structure 21 may include an element substrate such as a sapphire substrate.

The first semiconductor structure 21A has a first upper surface 21A1 and a first lower surface 21A2 located opposite to the first upper surface 21A1 in the third direction Z. The light-emitting layer of the first semiconductor structure 21A is, for example, closer to the first lower surface 21A2 than to the first upper surface 21A1. The second semiconductor structure 21B has a second upper surface 21B1 and a second lower surface 21B2 located opposite to the second upper surface 21B1 in the third direction Z. The light-emitting layer of the second semiconductor structure 21B is, for example, closer to the second lower surface 21B2 than to the second upper surface 21B1.

The first light-emitting element 20A has first element lateral surfaces 31. The first element lateral surface 31 includes a lateral surface of the first semiconductor structure 21A. The second light-emitting element 20B has second element lateral surfaces 32. The second element lateral surface 32 includes a lateral surface of the second semiconductor structure 21B. The second element lateral surface 32 faces the first element lateral surface 31 in the first direction X or the second direction Y.

The second light-emitting element 20B of the outer light-emitting units 10B located at the outermost peripheral portion among the plurality of light-emitting units 10 has third element lateral surfaces 33 not adjacent to other light-emitting units 10. The third element lateral surface 33 includes a lateral surface of the second semiconductor structure 21B. The third element lateral surface 33 does not face the first element lateral surface 31 of the first light-emitting element 20A of the inner light-emitting unit 10A and the second element lateral surface 32 of the other second light-emitting element 20B.

The light-emitting element 20 further includes positive and negative electrodes (i.e., a first positive electrode and a first negative electrode). The first light-emitting element 20A includes first positive and negative electrodes 22A disposed on the first lower surface 21A2 of the first semiconductor structure 21A. The second light-emitting element 20B includes second positive and negative electrodes 22B disposed on the second lower surface 21B2 of the second semiconductor structure 21B. The first positive and negative electrodes 22A and the second positive and negative electrodes 22B may be simply referred to as positive and negative electrodes 22 without being distinguished from each other. Examples of a material of the positive and negative electrodes 22 that can be used include a metal such as gold or copper.

The lower surfaces of the positive and negative electrodes 22 are bonded, via a conductive member such as a solder, to a wiring portion disposed on a wiring substrate where the light-emitting device 1 is mounted. The light-emitting element 20 is electrically connected to the wiring portion of the wiring substrate via the positive and negative electrodes 22. In addition, heat generated by the light-emitting element 20 in association with light emission can be released to the wiring substrate via the positive and negative electrodes 22. A metal film may be disposed on the lower surfaces of the positive and negative electrodes 22. The metal film can include, for example, a gold film, and a nickel film disposed between the gold film and the lower surfaces of the positive and negative electrodes 22.

### Light-transmissive Member

Each light-emitting unit 10 includes a light-transmissive member disposed over each light-emitting element 20. A light-transmissive member disposed over the first light-emitting element 20A is referred to as a first light-transmissive member 40A, and a light-transmissive member disposed over the second light-emitting element 20B is referred to as a second light-transmissive member 40B. The first light-transmissive member 40A and the second light-transmissive member 40B may be simply referred to as a light-transmissive member 40 without being distinguished from each other.

The first upper surface 21A1 of the first semiconductor structure 21A faces the first light-transmissive member 40A in the third direction Z. The first upper surface 21B1 of the second semiconductor structure 21B faces the second light-transmissive member 40B in the third direction Z. The first light-transmissive member 40A has first lateral surfaces 51. The second light-transmissive member 40B has second lateral surfaces 52 facing the first lateral surfaces 51 in the first direction X or the second direction Y.

The second light-transmissive member 40B of the outer light-emitting unit 10B located at the outermost peripheral portion among the plurality of light-emitting units 10 has a third lateral surface 53 not adjacent to the other light-emitting units 10. The third lateral surface 53 does not face the first lateral surface 51 of the first light-transmissive member 40A of the inner light-emitting unit 10A and the second lateral surface 52 of the other second light-transmissive member 40B.

As illustrated in FIG. 1, for example, in a plan view, an outer edge (indicated by a broken line) of the light-emitting element 20 is located inside an outer edge (indicated by a solid line) of the light-transmissive member 40. By the outer edge of the light-transmissive member 40 being located outside the outer edge of the light-emitting element 20 in a plan view, light emitted from the light-emitting element 20 is efficiently incident on the light-transmissive member 40. In a plan view, the outer edge of the light-transmissive member 40 may coincide with or may be located inside the outer edge of the light-emitting element 20. Thus, in a plan view, the light-emitting unit 10 can emit narrow-angle light with reduced spread of light as compared with when the outer edge of the light-transmissive member 40 is located outside the outer edge of the light-emitting element 20.

The light-transmissive member 40 has light transmissivity with respect to light emitted by the light-emitting element 20. For example, the transmittance of the light-transmissive member 40 with respect to light emitted by the light-emitting element 20 and having a wavelength of 450 nm is 70% or more, preferably 80% or more, more preferably 90% or more.

The light-transmissive member 40 can wavelength-convert and/or diffuse light emitted by the light-emitting element 20. The light-transmissive member 40 can include a phosphor layer 41 disposed over the light-emitting element 20 and a light diffusion layer 42 disposed on the phosphor layer 41.

The phosphor layer 41 includes a phosphor. Examples of the phosphor layer 41 that can be used include a resin, ceramic, glass, or the like containing a phosphor, and a sintered compact of a phosphor.

Examples of the resin of the phosphor layer 41 that can be used include a thermosetting resin such as a silicone resin, a modified silicone resin, an epoxy resin, a modified epoxy resin, and a phenol resin. In particular, a silicone resin or a modified resin thereof with superior light resistance and heat resistance is suitable for the resin of the phosphor layer 41.

Examples of the phosphor that can be used include an yttrium aluminum garnet-based phosphor (for example, (Y,Gd)₃(Al,Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), oxynitride-based phosphors such as a β-SiAlON-based phosphor (for example, (Si,Al)₃(O,N)₄:Eu) or an α-SiAlON-based phosphor (for example, Ca(Si,Al)₁₂(O,N)₁₆:Eu), nitride-based phosphors such as an LSN-based phosphor (for example, (La, Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), or an SCASN-based phosphor (for example, (Sr,Ca)AlSiN₃:Eu), fluoride-based phosphors such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), or an MGF-based phosphor (for example, 3.5 MgO·0.5 MgF₂·GeO₂:Mn), a quantum dot having a perovskite structure (for example, (Cs,FA,MA)(Pb,Sn)(F,Cl,Br,I)₃, where FA and MA represent formamidinium and methylammonium, respectively), a II-VI group quantum dot (for example, CdSe), a III-V group quantum dot (for example, InP), or a quantum dot having a chalcopyrite structure (for example, (Ag,Cu)(In,Ga)(S,Se)₂).

The phosphor layer 41 may include one type of phosphor, or may include a plurality of types of phosphors. For example, the light-emitting unit 10 emits light of a color obtained by mixing a color of visible light emitted by the light-emitting element 20 and a color of light emitted by the phosphor of the phosphor layer 41 excited by the light emitted by the light-emitting element 20. Alternatively, the light-emitting unit 10 emits light obtained by mixing ultraviolet light emitted by the light-emitting element 20 and light emitted by the phosphor of the phosphor layer 41 excited by the ultraviolet light emitted by the light-emitting element 20. The plurality of light-emitting units 10 may be composed of light-emitting units 10 having the same light emission peak wavelength or may include light-emitting units 10 having different light emission peak wavelengths from each other.

An upper surface of the light diffusion layer 42 constitutes an upper surface 40S of the light-transmissive member 40. The light-emitting surface of the light-emitting device 1 includes the upper surface 40S of the light-transmissive member 40. The light diffusion layer 42 includes a light diffusion material that diffuses light emitted by the light-emitting element 20. As the light diffusion layer 42, a resin, ceramic, glass, or the like containing a light diffusion material can be used. As the light diffusion material, for example, titanium oxide, silicon oxide, or the like can be used. As the resin of the light diffusion layer 42, the resin of the phosphor layer 41 can be used.

### Bonding Member

The light-emitting unit 10 may further include a bonding member 70. The bonding member 70 is disposed between an upper surface (the first upper surface 21A1 and the second upper surface 21B1) of the light-emitting element 20 and a lower surface of the light-transmissive member 40, and bonds the light-emitting element 20 and the light-transmissive member 40. In addition, the bonding member 70 covers a part of an upper surface side of element lateral surfaces (the first element lateral surface 31, the second element lateral surface 32, and the third element lateral surface 33) of the light-emitting element 20 and the lower surface of the light-transmissive member 40. As a material of the bonding member 70, a light-transmissive resin can be used, and for example, a silicone resin can be used. The upper surface of the light-emitting element 20 and the lower surface of the light-transmissive member 40 may be directly bonded.

### Reflective Member

The light-emitting device 1 further includes a reflective member 60 that holds the plurality of light-emitting units 10 together. The reflective member 60 has reflectivity with respect to light emitted by the light-emitting element 20 and light wavelength-converted by the phosphor of the phosphor layer 41. For example, a material whose main component is a thermosetting resin such as an epoxy resin, a silicone resin, a modified silicone resin, or a phenolic resin can be used as a base material of the reflective member 60. The reflective member 60 contains a light-reflective additive to be described below. The reflective member 60 includes a first reflective member 61 and a second reflective member 62.

The first reflective member 61 continuously covers the first element lateral surface 31 of the first light-emitting element 20A, the second element lateral surface 32 of the second light-emitting element 20B, the first lateral surface 51 of the first light-transmissive member 40A, and the second lateral surface 52 of the second light-transmissive member 40B. For example, the first reflective member 61 is in direct contact with and covers the first element lateral surface 31, the second element lateral surface 32, the first lateral surface 51, and the second lateral surface 52.

The second reflective member 62 is disposed between the first light-emitting element 20A and the second light-emitting element 20B. The second reflective member 62 covers the first reflective member 61 that covers the first element lateral surface 31 of the first light-emitting element 20A and the second element lateral surface 32 of the second light-emitting element 20B. The second reflective member 62 is not disposed between the first lateral surface 51 of the first light-transmissive member 40A and the second lateral surface 52 of the second light-transmissive member 40B. The second reflective member 62 is located below the first reflective member 61 disposed between the first lateral surface 51 of the first light-transmissive member 40A and the second lateral surface 52 of the second light-transmissive member 40B.

The first reflective member 61 contains a first additive, and the second reflective member 62 contains a second additive. A thermal conductivity of the second additive is higher than a thermal conductivity of the first additive. A light reflectance of the first additive is higher than a light reflectance of the second additive.

The thermal conductivity of the first additive is, for example, 0.05 W/m·K or more, preferably 0.1 W/m·K or more, more preferably 0.2 W/m·K or more. The thermal conductivity of the first additive is, for example, 10 W/m·K or less, preferably 5 W/m·K or less, more preferably 4 W/m·K or less. The thermal conductivity of the second additive is, for example, 10 W/m·K or more, preferably 20 W/m·K or more, more preferably 50 W/m·K or more. The thermal conductivity of the second additive is, for example, 320 W/m·K or less, preferably 280 W/m·K or less, more preferably 200 W/m·K or less.

The light reflectance of the first additive with respect to light emitted by the light-emitting element 20 and having a wavelength of 450 nm is, for example, in a range from 80% to 99%, and is, as an example, in a range from 90% to 99%. The light reflectance of the second additive with respect to the light emitted by the light-emitting element 20 and having a wavelength of 450 nm is in a range from 50% to 90%, and is, as an example, in a range from 60% to 85%.

The difference between the light reflectance of the first additive and the light reflectance of the second additive is, for example, 8% or more, 15% or more, 20% or more, or 40% or more.

The first additive contains, for example, titanium oxide. The second additive contains, for example, at least one selected from the group consisting of aluminum nitride, boron nitride, and aluminum oxide. The second additive is formed of, for example, an inorganic material containing boron nitride and alkali metal silicate. By using the exemplified material as the first additive or the second additive, the above-described predetermined thermal conductivity and the above-described predetermined light reflectance with respect to the light having a wavelength of 450 nm can be achieved.

According to the present embodiment, the first reflective member 61 containing the first additive having a higher light reflectance than the second additive of the second reflective member 62 continuously covers the first element lateral surface 31 of the first light-emitting element 20A, the second element lateral surface 32 of the second light-emitting element 20B, the first lateral surface 51 of the first light-transmissive member 40A, and the second lateral surface 52 of the second light-transmissive member 40B. Thus, when the first light-emitting unit (e.g., the inner light-emitting unit 10A in the present embodiment) emits light and the second light-emitting unit (e.g., the outer light-emitting unit 10B in the present embodiment) adjacent to the first light-emitting unit does not emit light, the light emitting device 1 according to the present disclosure can suppress light emitted by the first light-emitting unit from being incident on the second light-transmissive member 40B of the adjacent second light-emitting unit and causing light emission from the upper surface 40S of the second light-transmissive member 40B and light emission by the phosphor included in the second light-transmissive member 40B. As a result, the contrast on the irradiation surface of light emitted by the light-emitting device 1 can be increased.

In the light-emitting unit 10 in the light-emitting state, the temperature of the light-emitting element 20 is higher than the temperature of the light-transmissive member 40. According to the present embodiment, the second reflective member 62 containing the second additive having a thermal conductivity higher than a thermal conductivity of the first additive of the first reflective member 61 is disposed between the first light-emitting element 20A and the second light-emitting element 20B. Thus, heat generated by the light-emitting operation of the first light-emitting element 20A and/or the second light-emitting element 20B can be efficiently dissipated to the wiring substrate and the air via the second reflective member 62.

In addition to the first reflective member 61, the second reflective member 62 can also reduce the incidence of light emitted by the first light-emitting element 20A onto the second light-transmissive member 40B of an adjacent second light-emitting unit 10B that emits no light, and can easily increase the contrast on the irradiation surface of light emitted by the light-emitting device 1. The second reflective member 62 may further contain the first additive in addition to the second additive. This can further reduce the incidence of light emitted by the first light-emitting element 20A onto the second light-transmissive member 40B of the adjacent second light-emitting unit 10B that emits no light.

The first additive in the first reflective member 61 positioned closer to a light-emitting surface (the upper surface 40S of the light-transmissive member 40) of the light-emitting device 1 than the second reflective member 62 has light reflectance higher than light reflectance of the second additive in the second reflective member 62. This can easily increase the contrast in the irradiation surface of light emitted by the light-emitting device 1.

As described above, the light-emitting device 1 according to the first embodiment can emit light with a high contrast and increase heat dissipation.

As described above, when the light-emitting device 1 is used as, for example, a flash light source of an imaging device, the light-emitting mode of the light-emitting device 1 in the telephoto photographing mode of the imaging device is switched to the first light-emitting mode in which only the inner light-emitting unit 10A emits light. In the first light-emitting mode, only the inner light-emitting unit 10A (one inner light-emitting unit 10A in the example illustrated in FIG. 1) needs to emit light having a predetermined illuminance. Therefore, in the first light-emitting mode, the value of a current supplied to the first light-emitting element 20A of the inner light-emitting unit 10A is likely to increase, and the temperature of the first light-emitting element 20A is likely to increase.

The first light-emitting element 20A includes four first element lateral surfaces 31 each facing the second element lateral surfaces 32 of the second light-emitting elements 20B. The second reflective member 62 surrounds the first light-emitting element 20A and covers all of the four first element lateral surfaces 31 of the first light-emitting element 20A via the first reflective member 61. This can increase the heat dissipation of the first light-emitting element 20A whose temperature is likely to increase in the first light-emitting mode.

According to the present embodiment, the first reflective member 61 further covers the first lower surface 21A2 of the first semiconductor structure 21A and the second lower surface 21B2 of the second semiconductor structure 21B. Light emitted from the light-emitting layer toward the first lower surface 21A2 of the first semiconductor structure 21A and the second lower surface 21B2 of the second semiconductor structure 21B can be reflected by the first reflective member 61 and can travel toward the light-emitting surface of the light-emitting device 1. Thus, the luminance of the light-emitting device 1 can be improved.

According to the present embodiment, the second reflective member 62 is in contact with at least a part of the lateral surfaces of the first positive and negative electrodes 22A and at least a part of the lateral surfaces of the second positive and negative electrodes 22B. Thus, heat generated by the first light-emitting element 20A can be dissipated to the second reflective member 62 via the lateral surfaces of the first positive and negative electrodes 22A, and heat generated by the second light-emitting element 20B can be dissipated to the second reflective member 62 via the lateral surfaces of the second positive and negative electrodes 22B.

The lower surfaces of the first positive and negative electrodes 22A and the second positive and negative electrodes 22B are exposed from the second reflective member 62 and the first reflective member 61, the lower surface being a bonding surface to the wiring substrate. Heat generated by the light-emitting element 20 can be dissipated to the wiring substrate via the lower surfaces of the positive and negative electrodes 22. In a state in which the light-emitting device 1 is mounted on the wiring substrate, a lower surface of the second reflective member 62 can be bonded to an upper surface of the wiring substrate via a bonding member such as solder. The heat transferred from the light-emitting element 20 to the second reflective member 62 can be dissipated to the wiring substrate via the lower surface of the second reflective member 62 and the bonding member.

The temperature of the light-emitting layer is the highest in the semiconductor structure 21 in the light-emitting state. For example, the light-emitting layer included in the first semiconductor structure 21A is closer to the first lower surface 21A2 than to the first upper surface 21A1, and the light-emitting layer included in the second semiconductor structure 21B is closer to the second lower surface 21B2 than to the second upper surface 21B1. According to the present embodiment, the second reflective member 62 covers lateral surfaces of the light-emitting layer included in the first semiconductor structure 21A and lateral surfaces of the light-emitting layer included in the second semiconductor structure 21B. Thus, the temperature of the light-emitting layer can be easily reduced and the reliability of the light-emitting element 20 can be increased. In the example illustrated in FIG. 2, the second reflective member 62 covers the lateral surfaces of each of the light-emitting layer of the first semiconductor structure 21A and the light-emitting layer of the second semiconductor structure 21B via the first reflective member 61. Alternatively, the second reflective member 62 may directly cover the lateral surfaces of each of the light-emitting layer of the first semiconductor structure 21A and the light-emitting layer of the second semiconductor structure 21B.

According to the present embodiment, the first reflective member 61 further covers the third element lateral surface 33 of the second light-emitting element 20B and the third lateral surface 53 of the second light-transmissive member 40B in the outer light-emitting unit 10B located in the outer peripheral portion. This can reduce the proportion of light emitted to the outside from the third element lateral surface 33 and the third lateral surface 53 being the outermost lateral surfaces of the light-emitting unit 10. Reducing the proportion of light emitted to the outside from the outermost lateral surface of the light-emitting unit 10 can increase the difference in luminance between an upper surface of the light-emitting unit 10 in a light-emitting state and an upper surface of the first reflective member 61 covering the third element lateral surface 33 and the third lateral surface 53, on an upper surface of the light-emitting device 1, thereby achieving high contrast.

For example, a particle size of the second additive is greater than a particle size of the first additive. For example, the particle size of the second additive may be 1.5 times or more, 1.8 times or more, 4 times or more, or 10 times or more the particle size of the first additive. The particle size of the first additive is, for example, in a range from 0.05 μm to 0.5 μm, and is preferably in a range from 0.1 μm to 0.3 μm. The particle size of the second additive may be, for example, in a range from 0.2 82 m to 15 μm, and may be in a range from 0.2 μm to 0.6 μm as an example. As another example, the particle size of the second additive may be in a range from 0.8 μm to 1.5 μm, and as yet another example, may be in a range from 5 μm to 15 μm. The particle size of the additive in this case may be an average particle size or a median particle size. The average particle size is measured by, for example, a Fisher Sub-sieve sizer method (hereinafter, also referred to as “FSSS method”). Alternatively, the average particle size may be determined to be an arithmetic mean value of equivalent spherical diameters obtained by observing and selecting 50 or more and 1000 or less particles whose outlines can be confirmed by electron microscope observation using a scanning electron microscope (SEM) in a range of 1000 times to 20000 times depending on the particle size, and calculating equivalent spherical diameters of the selected particles using image processing software. The median particle size is measured by, for example, a laser diffraction scattering method.

A second distance in the first direction X or the second direction Y between the first element lateral surface 31 of the first light-emitting element 20A and the second element lateral surface 32 of the second light-emitting element 20B is preferably greater than a first distance in the first direction X or the second direction Y between the first lateral surface 51 of the first light-transmissive member 40A and the second lateral surface 52 of the second light-transmissive member 40B. Thus, the second additive having a larger particle size than the first additive can be easily disposed between the first element lateral surface 31 of the first light-emitting element 20A and the second element lateral surface 32 of the second light-emitting element 20B.

By setting the first distance between the first lateral surface 51 of the first light-transmissive member 40A and the second lateral surface 52 of the second light-transmissive member 40B to be smaller than the second distance between the first element lateral surface 31 and the second element lateral surface 32, a dark region between the first light-transmissive member 40A and the second light-transmissive member 40B on the light-emitting surface of the light-emitting device 1 can be narrowed. The first distance is preferably in a range from 5 μm to 30 μm, for example. When the first distance is 5 82 m or more, in the vicinity of the light-emitting surface of one light-emitting unit, light emitted from the one light-emitting unit can be suppressed from reaching an adjacent light-emitting unit side. Thus, the light-emitting device having good contrast can be obtained. In addition, by setting the first distance to 30 um or less, when a body color of the light-transmissive member and a body color of the reflective member are different from each other, the difference in body color between the reflective member and the light-transmissive member at the time of non-light emission is less noticeable. Thus, the light-emitting device having a good appearance at the time of non-light emission can be obtained. The light-emitting device having the good appearance refers to, for example, a light-emitting device having a simple appearance in which a difference in color between portions is not emphasized at the time of non-light emission.

The first reflective member 61 includes, for example, a dimethyl silicone resin as the base material and titanium oxide as the first additive. The second reflective member 62 includes, for example, phenyl silicone resin as the base material and aluminum nitride as the second additive.

The refractive index difference between the dimethyl silicone resin and the titanium oxide is greater than the refractive index difference between the phenyl silicone resin and the titanium oxide. Consequently, in the first reflective member 61 containing the dimethyl silicone resin and the titanium oxide, the reflectance at an interface between the resin and the titanium oxide can be made higher than that in the configuration containing the phenyl silicone resin and the titanium oxide.

### First Variation

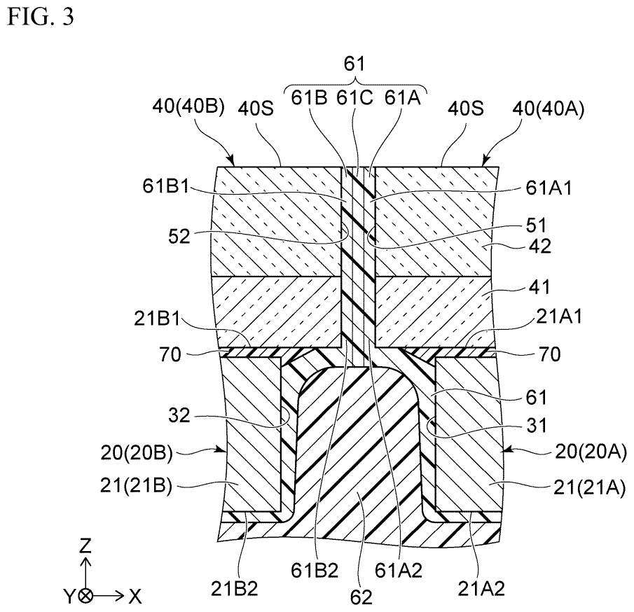

As illustrated in FIG. 3, according to a light-emitting device of a first variation of the first embodiment, the first reflective member 61 located between the first lateral surface 51 of the first light-transmissive member 40A and the second lateral surface 52 of the second light-transmissive member 40B includes a first portion 61A covering the first lateral surface 51, a second portion 61B covering the second lateral surface 52, and a third portion 61C located between the first portion 61A and the second portion 61B. A width of each of the first portion 61A and the second portion 61B is greater than the particle size of the first additive.

A concentration of the first additive in the first portion 61A and a concentration of the first additive in the second portion 61B are higher than a concentration of the first additive in the third portion 61C. The concentration of the first additive in the first portion 61A and the concentration of the first additive in the second portion 61B are, for example, in a range from 1.1 times to 9 times, preferably in a range from 2 times to 6 times, more preferably in a range from 3 times to 5 times the concentration of the first additive in the third portion 61C. Consequently, the first reflective member 61, between the first lateral surface 51 of the first light-transmissive member 40A and the second lateral surface 52 of the second light-transmissive member 40B, has a configuration in which the third portion 61C having a lower refractive index than the first portion 61A and the second portion 61B is interposed between the first portion 61A and the second portion 61B each having a higher refractive index than the third portion 61C. In the first reflective member 61, between the first lateral surface 51 and the second lateral surface 52, a refractive index difference is present in a direction connecting the first lateral surface 51 and the second lateral surface 52. Thus, when only one of the first light-emitting unit 10A and the second light-emitting unit 10B adjacent to each other is in a light-emitting state, light emitted from one of the first lateral surface 51 of the first light-transmissive member 40A and the second lateral surface 52 of the second light-transmissive member 40B is less likely to be incident on the other, and high contrast can be achieved.

The concentration of the first additive can be regarded as, for example, the number of first additives per unit area in a cross-sectional image obtained by a scanning electron microscope (SEM).

The concentration of the first additive in a first upper portion 61A1 of the first portion 61A is higher than the concentration of the first additive in a first lower portion 61A2 closer to the first light-emitting element 20A than the first upper portion 61A1 of the first portion 61A. The concentration of the first additive in the first upper portion 61A1 of the first portion 61A is, for example, in a range from 1.05 times to 4 times, preferably in a range from 1.1 times to 2 times, more preferably in a range from 1.2 times to 1.5 times the concentration of the first additive in the first lower portion 61A2. The first upper portion 61A1 is closer to the upper surface 40S of the first light-transmissive member 40A than the first lower portion 61A2. The concentration of the first additive in a second upper portion 61B1 of the second portion 61B is higher than the concentration of the first additive in a second lower portion 61B2 closer to the second light-emitting element 20B than the second upper portion 61B1 of the second portion 61B. The second upper portion 61B1 is closer to the upper surface 40S of the second light-transmissive member 40B than the second lower portion 61B2.

In the first portion 61A and the second portion 61B, the concentration of the first additive in an upper portion located closer to the light-emitting surface of the light-emitting device 1 is higher than the concentration of the first additive in a lower portion. Thus, when only one of the first light-emitting unit 10A and the second light-emitting unit 10B adjacent to each other is in a light-emitting state, light emitted from the light-transmissive member 40 of the light-emitting unit 10 emitting light is less likely to be emitted to the laterally outside of the upper surface 40S, and high contrast can be achieved.

### Second Variation

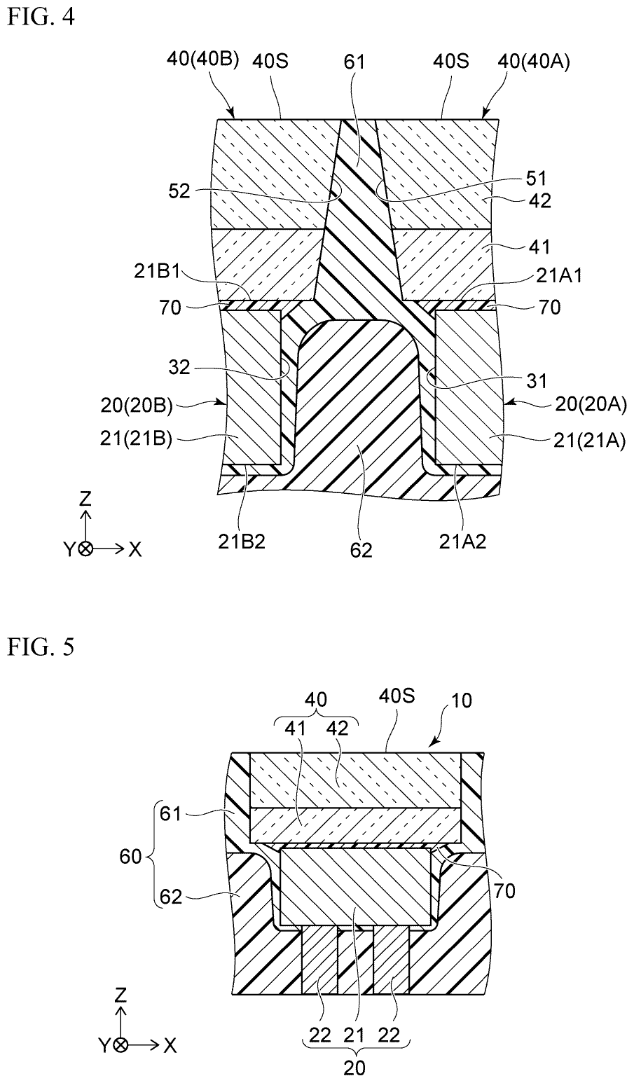

As illustrated in FIG. 4, according to a light-emitting device of a second variation of the first embodiment, the first lateral surface 51 of the first light-transmissive member 40A and the second lateral surface 52 of the second light-transmissive member 40B are inclined such that a distance between the first lateral surface 51 and the second lateral surface 52 increases from the upper end toward the lower end of the first lateral surface 51 and the second lateral surface 52. When the first lateral surface 51 and the second lateral surface 52 are inclined in this manner, light that enters the light-transmissive member 40 from the light-emitting element 20 and travels toward the first lateral surface 51 or the second lateral surface 52 is reflected by the first lateral surface 51 or the second lateral surface 52 and directed upward, and is easily emitted from the upper surface 40S of the light-transmissive member 40.

### Third Variation

In the light-emitting device 1 illustrated in FIG. 2, a thickness of each of the positive and negative electrodes 22 in the third direction Z is about 40 82 m, which is smaller than a thickness of the semiconductor structure 21 in the third direction Z. On the other hand, as illustrated in FIG. 5, according to a light-emitting device of a third variation of the first embodiment, a thickness of each of the positive and negative electrodes 22 in the third direction Z is equal to or greater than the thickness of the semiconductor structure 21 in the third direction Z. For example, the thickness of each of the positive and negative electrodes 22 in the third direction Z is about 255 μm, and the thickness of the semiconductor structure 21 in the third direction Z is about 250 μm. In the present variation, the thickness of the semiconductor structure 21 in the third direction Z may be a thickness including the thickness of the element substrate. Each of the positive and negative electrodes 22 includes, for example, an electrode of the light-emitting element 20 and a metal member formed on an electrode surface of the electrode of the light-emitting element 20. The metal member includes, for example, copper.

By setting the thickness of each of the positive and negative electrodes 22 to be equal to or greater than the thickness of the semiconductor structure 21, an area of a lateral surface of each of the positive and negative electrodes 22 that is in contact with the second reflective member 62 can be increased, and the heat dissipation of the light-emitting element 20 can be increased.

### Fourth Variation

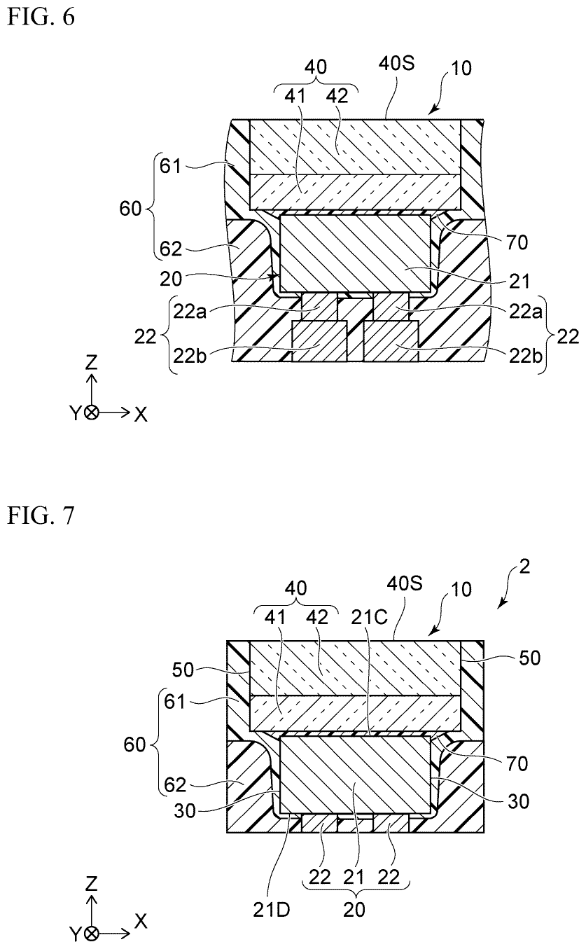

As illustrated in FIG. 6, according to a light-emitting device of a fourth variation of the first embodiment, each of the positive and negative electrodes 22 includes a first electrode portion 22a disposed on a lower surface of the semiconductor structure 21 and a second electrode portion 22b disposed on a lower surface of the first electrode portion 22a. A lower surface of the second electrode portion 22b is a surface to be bonded to the wiring substrate via solder or the like. A width of the first electrode portion 22a in the first direction X or the second direction Y is different from a width of the second electrode portion 22b in the first direction X or the second direction Y. For example, the width of the second electrode portion 22b is greater than the width of the first electrode portion 22a. By providing the second electrode portion 22b having a large width, even when the electrode of the light-emitting element 20 is small, the electrode portion exposed on the lower surface of the light-emitting device can be made large. This facilitates mounting on the wiring substrate via solder or the like. A thickness of each of the positive and negative electrodes 22 is equal to or greater than the thickness of the semiconductor structure 21 in the third direction Z. Thus, an area of a lateral surface of each of the positive and negative electrodes 22 that is in contact with the second reflective member 62 can be increased, and the heat dissipation of the light-emitting element 20 can be increased. In the present variation, the thickness of the semiconductor structure 21 in the third direction Z may be a thickness including the thickness of the element substrate. Each of the positive and negative electrodes 22 includes, for example, an electrode of the light-emitting element 20, a first electrode portion 22a formed on an electrode surface of the electrode of the light-emitting element 20, and a second electrode portion 22b disposed on a lower surface of the first electrode portion 22a. The first electrode portion 22a and the second electrode portion 22b include, for example, copper. The width of the first electrode portion 22a may be greater than the width of the second electrode portion 22b.

### Second Embodiment

FIG. 7 is a schematic cross-sectional view of a light-emitting device 2 according to a second embodiment. The light-emitting device 2 according to the second embodiment includes one light-emitting unit 10. The light-emitting unit 10 includes a light-emitting element 20 having element lateral surfaces 30 and a light-transmissive member 40 disposed over the light-emitting element 20 and having lateral surfaces 50. The light-emitting element 20 includes a semiconductor structure 21 and positive and negative electrodes 22 disposed on a lower surface 21D of the semiconductor structure 21. A lower surface of the light-transmissive member 40 faces an upper surface 21C of the semiconductor structure 21. The light-emitting element 20 and the light-transmissive member 40 are bonded to each other by a bonding member 70, for example. The light-transmissive member 40 includes a phosphor layer 41 disposed over the light-emitting element 20 and a light diffusion layer 42 disposed on the phosphor layer 41. A light-emitting surface of the light-emitting device 2 includes an upper surface 40S of the light-transmissive member 40.

The light-emitting device 2 further includes a reflective member 60. The reflective member 60 includes a first reflective member 61 and a second reflective member 62.

The first reflective member 61 continuously covers an element lateral surface 30 of the light-emitting element 20 and a lateral surface 50 of the light-transmissive member 40. For example, the first reflective member 61 is in direct contact with and covers the element lateral surface 30 and the lateral surface 50.

The first reflective member 61 covers the lower surface 21D of the semiconductor structure 21. The first reflective member 61 is in contact with at least a part of lateral surfaces of the positive and negative electrodes 22.

The second reflective member 62 covers the first reflective member 61 covering the element lateral surface 30 of the light-emitting element 20. The second reflective member 62 covers the element lateral surface 30 of the light-emitting element 20 via the first reflective member 61. The second reflective member 62 surrounds the element lateral surface 30 of the light-emitting element 20. The second reflective member 62 is in contact with at least a part of the lateral surfaces of the positive and negative electrodes 22.

The second reflective member 62 covers a lateral surface of a light-emitting layer included in the semiconductor structure 21. The second reflective member 62 covers the lateral surface of the light-emitting layer included in the semiconductor structure 21 via the first reflective member 61. Alternatively, the second reflective member 62 may directly cover the lateral surface of the light-emitting layer of the semiconductor structure 21.

As in the first embodiment, the first reflective member 61 contains a first additive and the second reflective member 62 contains a second additive. A thermal conductivity of the second additive is higher than a thermal conductivity of the first additive. A light reflectance of the first additive is higher than a light reflectance of the second additive.

According to the second embodiment, in the light-emitting surface of the light-emitting device 2, the luminance difference between the upper surface 40S (light-emitting region) of the light-transmissive member 40 and an upper surface (non-light-emitting region) of the first reflective member 61 covering the lateral surface 50 of the light-transmissive member 40 can be increased, and high contrast can be obtained. In addition, heat generated by the light-emitting element 20 can be dissipated via the second reflective member 62.

### Method for Manufacturing Light-emitting Device

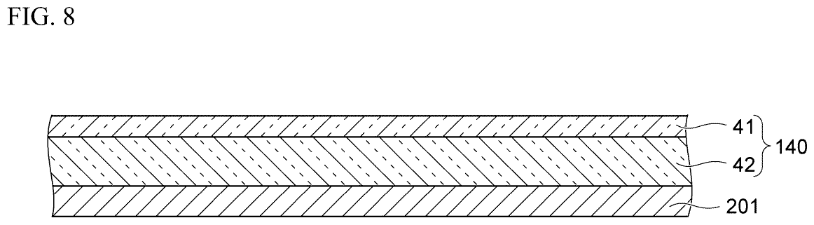

A method for manufacturing the light-emitting device according to the first embodiment is described with reference to FIGS. 8 to 16. The method for manufacturing the light-emitting device according to the first embodiment can include the steps described below.

As illustrated in FIG. 8, a light-transmissive sheet 140 is prepared. The light-transmissive sheet 140 is supported on a first support member 201. The light-transmissive sheet 140 includes a light diffusion layer 42 disposed on the first support member 201 and a phosphor layer 41 disposed on the light diffusion layer 42. For example, a thickness of the light diffusion layer 42 is about 180 um, and a thickness of the phosphor layer 41 is about 60 um.

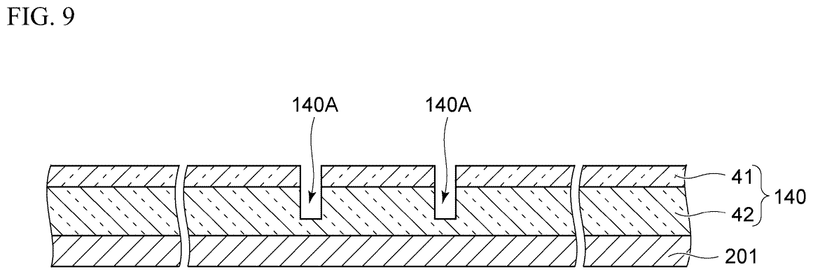

After the light-transmissive sheet 140 is prepared, grooves 140A are formed in the light-transmissive sheet 140 as illustrated in FIG. 9. For example, the groove 140A can be formed with a blade or a laser. The groove 140A extends through the phosphor layer 41, and a bottom of the groove 140A is located in the light diffusion layer 42. For example, a plurality of the grooves 140A are formed in a lattice shape in a plan view. A width of the groove 140A is about 20 μm.

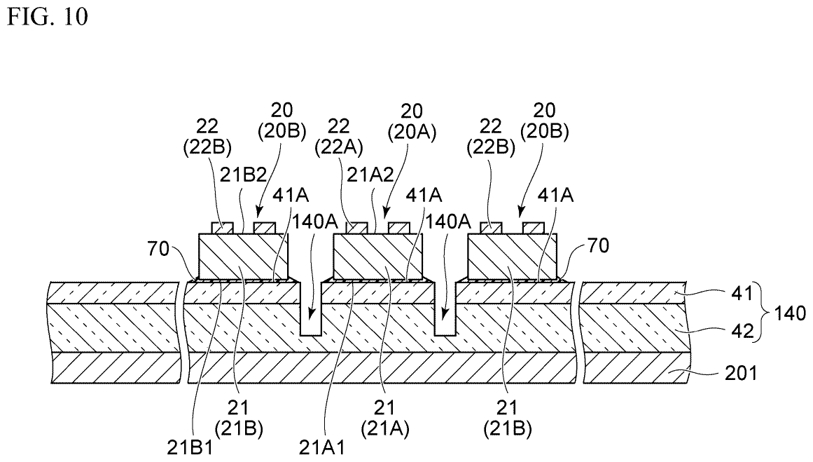

After the grooves 140A are formed, a plurality of light-emitting elements 20 are disposed on the phosphor layer 41 as illustrated in FIG. 10. Surfaces (the first upper surface 21A1 and the second upper surface 21B1 described above) of the light-emitting elements 20 on the side opposite to surfaces (the first lower surface 21A2 and the second lower surface 21B2 described above) on which the positive and negative electrodes 22 are disposed face a surface 41A of the phosphor layer 41 on the side opposite to the light diffusion layer 42.

For example, a bonding member 70 in an uncured state is supplied onto the surface 41A of the phosphor layer 41 by a dispenser or the like. After the bonding member 70 is supplied, the bonding member 70 is cured by heating, for example. Thus, the light-emitting element 20 is bonded to the light-transmissive sheet 140 by the bonding member 70. The light-emitting element 20 and the phosphor layer 41 may be directly bonded to each other without using the bonding member 70.

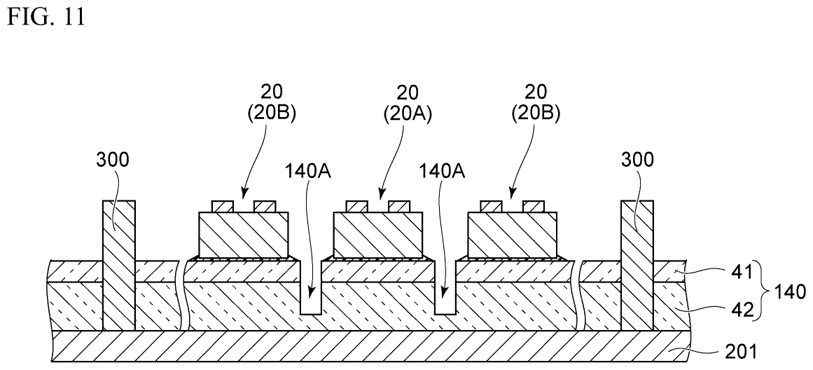

After the light-emitting elements 20 are disposed on the light-transmissive sheet 140, a frame member 300 is disposed on the first support member 201 as illustrated in FIG. 11. The frame member 300 extends through the light-transmissive sheet 140 and reaches the first support member 201. In the example illustrated in FIG. 11, a portion to be one light-emitting device 1 similar to the above-described cross-sectional view of FIG. 2 is illustrated; however, the frame member 300 surrounds a portion to be at least one light-emitting device 1. The frame member 300 may surround each portion to be one light-emitting device 1, or may surround portions to be two or more light-emitting devices 1. The frame member 300 is, for example, a resin member. A height of the frame member 300 is greater than a thickness of the light-transmissive sheet 140 and is, for example, about 500 um.

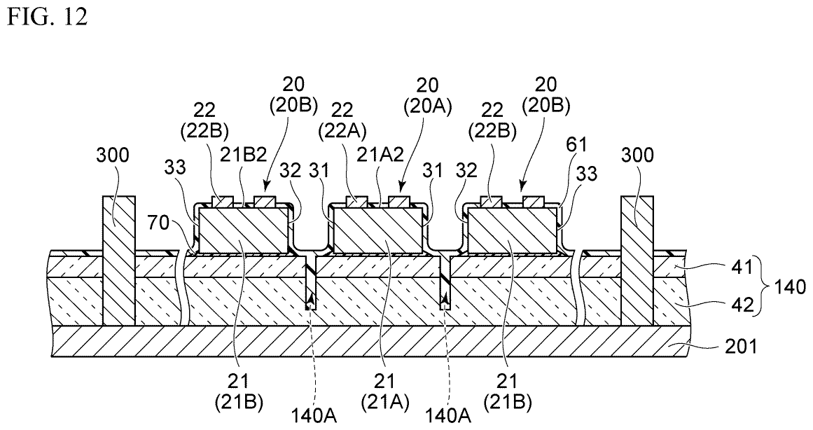

After the frame member 300 is disposed, a first reflective member 61 is formed as illustrated in FIG. 12. The first reflective member 61 is formed in the groove 140A and covers at least a part of element lateral surfaces (a first element lateral surface 31, a second element lateral surface 32, and a third element lateral surface 33) of the light-emitting element 20. In addition, the first reflective member 61 covers a surface of the phosphor layer 41 and the bonding member 70.

In the step of forming the first reflective member 61, for example, a solution obtained by dissolving or mixing a base material resin and the first additive in an organic solvent is supplied to the region surrounded by the frame member 300. Subsequently, the solution is heated to evaporate the organic solvent and cure the base material resin.

The liquid level of the solution can be adjusted by controlling a supply amount of the solution supplied to the inside of the frame member 300. By making the liquid level of the solution higher than the first lower surface 21A2 and the second lower surface 21B2 (upper surfaces in FIG. 12) of the light-emitting element 20, the first reflective member 61 can cover the entire element lateral surfaces of the light-emitting element 20, the first lower surface 21A2, the second lower surface 21B2, and a part of the lateral surfaces of the positive and negative electrodes 22.

By supplying the solution containing the base material resin, the first additive, and the organic solvent to the position where the first reflective member 61 is to be formed, unevenness in the thickness of the first reflective member 61 covering the element lateral surfaces of the plurality of light-emitting elements 20 can be reduced.

The solution contains, for example, a dimethyl silicone resin as the base material resin, titanium oxide as the first additive, and heptane, tridecane, and butyl carbitol acetate as the organic solvent. For example, the mixing ratio of heptane, tridecane, and butyl carbitol acetate in the organic solvent can be 80:15:5. After the solution is supplied, for example, the solution is heated at a temperature in a range from 60° C. to 80° C. for several minutes and then is heated at 150° C. for 4 hours, thereby evaporating the organic solvent (heptane, tridecane, and butyl carbitol acetate) and curing the dimethyl silicone resin.

The dimethyl silicone resin is cured at about 100° C., for example. Because the boiling point of tridecane is 235° C., if tridecane still remains when the dimethyl silicone resin is cured, cracks may occur in the dimethyl silicone resin. Therefore, by adding heptane having a boiling point of 98° C., the occurrence of cracks when the dimethyl silicone resin is cured can be reduced. When titanium oxide is mixed with heptane and tridecane, titanium oxide tends to aggregate. Therefore, by further adding butyl carbitol acetate in addition to heptane and tridecane, the aggregation of titanium oxide can be reduced.

By forming the first reflective member 61, the width of the groove 140A is reduced. For example, the width of the groove 140A, which is about 20 um before the formation of the first reflective member 61, is reduced to about 10 um after the formation of the first reflective member 61, that is, after the organic solvent is evaporated and the base material resin is cured. This mechanism is presumed as follows.

Before the dimethyl silicone resin is completely cured by heating, a part of the organic solvent evaporates, and the volume of the organic solvent in the groove 140A decreases. As the volume of the organic solvent in the groove 140A decreases, the uncured dimethyl silicone resin pulls the lateral surface of the light-transmissive member 40 defining the groove 140A toward the inside of the groove 140A, so that the width of the groove 140A decreases. In addition, the base material resin (for example, phenyl silicone resin) of the light-transmissive member 40 absorbs the organic solvent and swells, and the volume of the light-transmissive member 40 increases, so that the width of the groove 140A decreases. In particular, butyl carbitol acetate is easily absorbed by phenyl silicone resin being the base material resin of the light-transmissive member 40.

When the base material resin of the light-transmissive member 40 absorbs the organic solvent, the first additive located in the groove 140A moves toward the light-transmissive member 40. Thus, as described above with reference to FIG. 3, in the first reflective member 61 located between the first lateral surface 51 of the first light-transmissive member 40A and the second lateral surface 52 of the second light-transmissive member 40B, a concentration of the first additive in the first portion 61A covering the first lateral surface 51 and a concentration of the first additive in the second portion 61B covering the second lateral surface 52 are higher than a concentration of the first additive in the third portion 61C.

Because the first additive located in the groove 140A moves to the lower side of the groove 140A by the gravity, a concentration of the first additive in a region of the groove 140A on the light diffusion layer 42 side being the light-emitting surface side of the light-emitting device 1 is higher than a concentration of the first additive in a region of the groove 140A on the phosphor layer 41 side. That is, as described above, in FIG. 3, a concentration of the first additive in the upper portion of the first portion 61A and the second portion 61B located on the light-emitting surface side of the light-emitting device 1 is higher than a concentration of the first additive in the lower portion of the first portion 61A and the second portion 61B.

By reducing the width of the groove 140A, in other words, the width of the first reflective member 61 located between the lateral surfaces of adjacent light-transmissive members 40, occurrence of a region between the lateral surfaces of the adjacent light-transmissive members 40 becoming a bright line when the light-emitting device 1 emits light can be reduced.

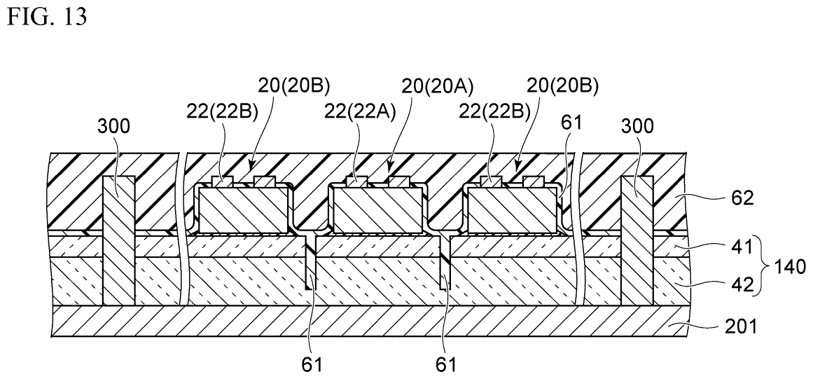

After the first reflective member 61 is formed, the second reflective member 62 is formed as illustrated in FIG. 13. The second reflective member 62 covers the first reflective member 61 and the light-emitting element 20. The second reflective member 62 is disposed between adjacent light-emitting elements 20. The second reflective member 62 covers an upper surface and lateral surfaces of the frame member 300.

The second reflective member 62 can be formed by, for example, a compression molding method using a mold, a transfer molding method, an injection molding method, or the like. After the uncured second reflective member 62 is supplied, for example, first heating processing is performed at 120° C. for several minutes, and subsequently, second heating processing is performed at 150° C. for four hours to cure the second reflective member 62.

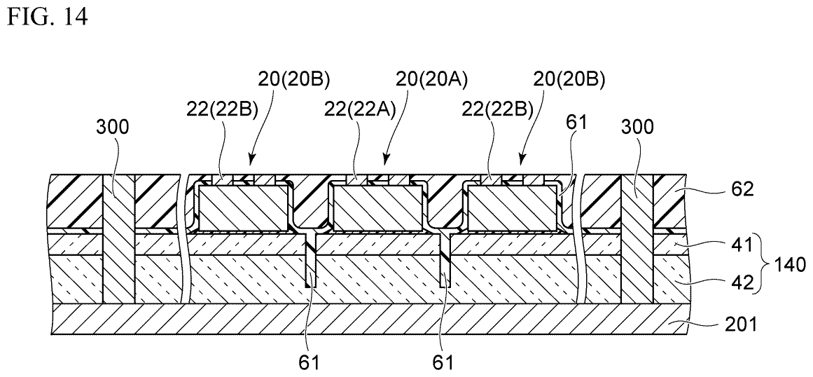

After the second reflective member 62 is formed, the second reflective member 62 is removed from the upper surface side by using, for example, a grinder, and surfaces of the positive and negative electrodes 22 of the light-emitting element 20 are exposed from the second reflective member 62 as illustrated in FIG. 14. Subsequently, a metal film is formed on the surfaces of the positive and negative electrodes 22 as needed. As the metal film, for example, a nickel film and a gold film are sequentially formed from the surface side of the positive and negative electrodes 22. The metal film can be formed by a sputtering method or a vapor deposition method, for example.

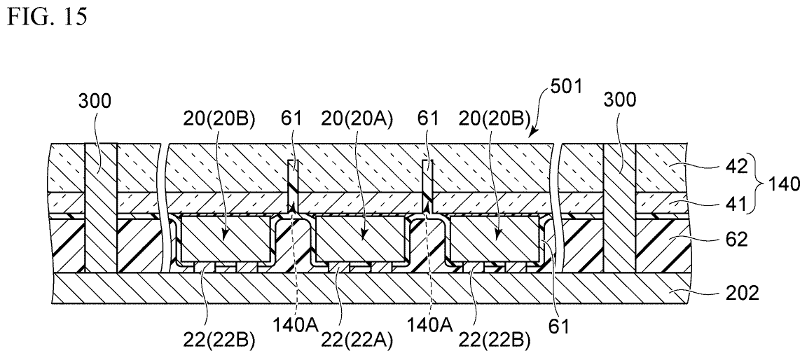

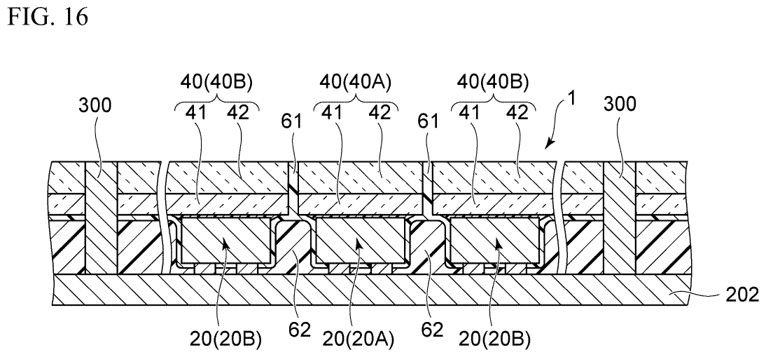

After the surfaces of the positive and negative electrodes 22 are exposed and the metal film is formed as needed, as illustrated in FIG. 15, a structure 501 including the light-transmissive sheet 140, the light-emitting elements 20, the first reflective member 61, and the second reflective member 62 is vertically inverted such that the light diffusion layer 42 is on the upper side, and is transferred from the first support member 201 to a second support member 202. Subsequently, a part of the light diffusion layer 42 is removed using a grinder, for example. The light diffusion layer 42 is removed until the first reflective member 61 disposed in the grooves 140A is exposed. Thus, the light-transmissive sheet 140 is divided into a plurality of light-transmissive members 40 as illustrated in FIG. 16.

Subsequently, the light diffusion layer 42, the phosphor layer 41, the first reflective member 61, and the second reflective member 62 are cut by using, for example, a blade or a laser inside the frame member 300 and at a position where the light-emitting element 20 is not disposed, and are singulated into the light-emitting device 1.

Embodiments of the present invention have been described above with reference to specific examples. However, the present invention is not limited to these specific examples. All aspects that can be practiced by a person skilled in the art modifying the design as appropriate based on the above-described embodiments of the present invention are also included in the scope of the present invention, as long as they encompass the spirit of the present invention. In addition, in the scope of the concepts of the present invention, a person skilled in the art can conceive of various modifications and alterations, and those modifications and alterations also fall within the scope of the present invention.

What is claimed is:

1. A light-emitting device comprising:
a first light-emitting unit comprising:
a first light-emitting element having a first element lateral surface, and
a first light-transmissive member disposed over the first light-emitting element and having a first lateral surface;
a second light-emitting unit comprising:
a second light-emitting element having a second element lateral surface facing the first element lateral surface, and
a second light-transmissive member disposed over the second light-emitting element and having a second lateral surface facing the first lateral surface; and
a reflective member holding the first light-emitting unit and the second light-emitting unit together, wherein the reflective member comprises:
a first reflective member continuously covering the first element lateral surface, the second element lateral surface, the first lateral surface, and the second lateral surface, and containing a first additive, and
a second reflective member disposed between the first light-emitting element and the second light-emitting element, and containing a second additive having a thermal conductivity higher than a thermal conductivity of the first additive, wherein:
a light reflectance of the first additive is higher than a light reflectance of the second additive.

2. The light-emitting device according to claim 1, wherein:
a plurality of the second light-emitting units surround the first light-emitting unit;
the light-emitting device is switchable between a first light-emitting mode in which only the first light-emitting unit emits light, and a second light-emitting mode in which the first light-emitting unit and the plurality of the second light-emitting units emit light;
a light distribution angle of light emitted by the light-emitting device in the second light-emitting mode is wider than a light distribution angle of light emitted by the light-emitting device in the first light-emitting mode; and
the second reflective member surrounds at least the first light-emitting element.

3. The light-emitting device according to claim 1, wherein:
the first light-emitting element comprises:
a first semiconductor structure having a first upper surface facing the first light-transmissive member and a first lower surface located opposite to the first upper surface, and
a first positive electrode and a first negative electrode disposed on the first lower surface;
the second light-emitting element comprises:
a second semiconductor structure having a second upper surface facing the second light-transmissive member and a second lower surface located opposite to the second upper surface, and
a second positive electrode and a second negative electrode disposed on the second lower surface; and
the first reflective member further covers the first lower surface of the first semiconductor structure and the second lower surface of the second semiconductor structure.

4. The light-emitting device according to claim 3, wherein the second reflective member is in contact with at least a part of a lateral surface of the first positive electrode or the first negative electrode and at least a part of a lateral surface of the second positive electrode or the second negative electrode.

5. The light-emitting device according to claim 3, wherein the second reflective member covers a lateral surface of a light-emitting layer of the first semiconductor structure and a lateral surface of a light-emitting layer of the second semiconductor structure.

6. The light-emitting device according to claim 1, wherein:
the first reflective member comprises a first portion covering the first lateral surface, a second portion covering the second lateral surface, and a third portion located between the first portion and the second portion, and
a concentration of the first additive in the first portion and a concentration of the first additive in the second portion are higher than a concentration of the first additive in the third portion.

7. The light-emitting device according to claim 6, wherein:
the first portion comprises a first upper portion, and a first lower portion closer to the first light-emitting element than the first upper portion;
a concentration of the first additive in the first upper portion is higher than a concentration of the first additive in the first lower portion;
the second portion comprises a second upper portion, and a second lower portion closer to the second light-emitting element than the second upper portion; and
a concentration of the first additive in the second upper portion is higher than a concentration of the first additive in the second lower portion.

8. The light-emitting device according to claim 1, wherein the first lateral surface and the second lateral surface are inclined such that a distance between the first lateral surface and the second lateral surface increases from an upper end toward a lower end of each of the first lateral surface and the second lateral surface.

9. The light-emitting device according to claim 1, wherein a distance between the first lateral surface and the second lateral surface is in a range from 5 μm to 30 μm.

10. The light-emitting device according to claim 1, wherein:
at least one of the first light-emitting element or the second light-emitting element has a third element lateral surface not adjacent to another light-emitting unit;
at least one of the first light-transmissive member or the second light-transmissive member has a third lateral surface not adjacent to another light-emitting unit; and
the first reflective member further covers the third element lateral surface and the third lateral surface.

11. The light-emitting device according to claim 1, wherein the second reflective member further contains the first additive.

12. A light-emitting device comprising:
a light-emitting unit comprising:
a light-emitting element having an element lateral surface, and
a light-transmissive member disposed over the light-emitting element and having a lateral surface;
a first reflective member covering the element lateral surface of the light-emitting element and the lateral surface of the light-transmissive member, the first reflective member containing a first additive; and
a second reflective member covering a portion of the first reflective member that covers the element lateral surface of the light-emitting element, the second reflective member containing a second additive having a thermal conductivity higher than a thermal conductivity of the first additive;
wherein a light reflectance of the first additive is higher than a light reflectance of the second additive.

13. The light-emitting device according to claim 1, wherein the first additive contains titanium oxide.

14. The light-emitting device according to claim 1, wherein the second additive contains at least one of aluminum nitride, boron nitride, or aluminum oxide.
